(19) United States
(12) Patent Application Publication
(10) Pub. No.: US 2016/0102964 A1
(43) Pub. Date: Apr. 14, 2016

(54) Methods and Systems for Estimating Distance of a Radio Frequency Identification Tag

(71) Applicant: Lexmark International, Inc., Lexington, KY (US)

(72) Inventors: John Thomas Fessler, Lexington, KY (US); Zachary Charles Nathan Kratzer, Lexington, KY (US); Johne Michelle Parker, Lexington, KY (US); Ann Michelle Whitney, Georgetown, KY (US); Julie Ann Gordon Whitney, Georgetown, KY (US)

(21) Appl. No.: 14/510,855

(22) Filed: Oct. 9, 2014

(51) Int. Cl. G01B 7/14; G06K 19/07; G01R 25/00

(52) U.S. Cl. CPC G01B 7/14; G01R 25/00; G06K 19/0723

(57) ABSTRACT

A localization method and system, including determining phases of a plurality of response signals at a plurality of frequencies received from a radio frequency identification (RFID) tag in response to interrogation signals by a reader at the plurality of frequencies; calculating a first distance estimate of a distance between the RFID tag and the reader based on a signal strength measured from a first response signal of the plurality of response signals; based on the phases and the first distance estimate, calculating a phase slope; and determining a second distance estimate of the distance based upon the phase slope.

### CROSS REFERENCES TO RELATED APPLICATIONS

None.

### STATEMENT REGARDING FEDERALLY SPONSORED RESEARCH OR DEVELOPMENT

None.

### REFERENCE TO SEQUENTIAL LISTING, ETC.

None.

### BACKGROUND

1. Field of the Disclosure

The present disclosure relates generally to radio frequency identification (RFID) systems, more particularly, to methods for estimating distance of an RFID tag.

2. Description of the Related Art

In recent years, localization systems have been used in many applications to identify and track different physical entities such as merchandise, equipment, devices, personnel or individuals, and other items or assets that need to be monitored within a particular environment. Example applications include supply chain management applications where localization systems are used for automatic inventory and tracking, and security applications where such services are used to identify and monitor personnel to control access to particular areas within a facility.

Radio frequency identification (RFID) systems have been widely employed for localization due to relatively low implementation cost. An RFID system typically attaches an RFID tag to an object to be monitored. Readers are then deployed in the environment to interrogate the tag as the tagged object passes within range of the readers. The readers transmit radio frequency (RF) signals to the tag which in turn responds by transmitting an RF response signal containing information identifying the object to which the tag is attached. The response signals received by each reader are then transformed into distance measurements which are utilized to determine an estimate of the location of the tagged object.

One conventional approach of making distance measurements between a tag and a reader is by using received signal strength indicator (RSSI). Typically, signal strength of a response signal returned by an RFID tag in response to an interrogation signal transmitted by a reader can be used to estimate distance. As the distance between the tag and reader increases, signal strength of a response signal decreases. RSSI is a fast way of obtaining distance measurements, but is greatly sensitive to changes in the environment. More particularly, changes in the environment, such as when new objects are added in the environment that may modify, block, or reflect RFID signals, can cause variations in signal strength which can compromise reliability when performing distance estimations using RSSI method. Thus, RSSI method can provide a fast and simple way to indicate distance, but cannot be relied upon in changing environments.

In some other approaches, phase angles of response signals are used to calculate distance measurements. The reader transmits interrogation signals at a plurality of frequencies, and receives response signals from the RFID tag at each of the plurality of frequencies. Keeping all else substantially constant including reader to tag distance, a response signal for a given frequency typically has a specific phase angle, and as the frequency changes, phase angle also changes. An example graph 10 shown in FIG. 1A illustrates a plurality of phase angle measurements taken at 50 different hop frequencies over a frequency range for a given tag to reader distance. As shown, the change in phase angle as a function of change in frequency is generally periodic and follows a sawtooth wave shape 15. The change in phase angle with respect to the change in frequency is proportional to the reader to tag distance, and thus can be used to determine a distance estimate between tag and reader. In order to calculate the rate of change of the phase over the range of frequencies, the sawtooth wave 15 in FIG. 1A can be transformed into a substantially linear function by altering the phase angles at appropriate locations until a linear phase trend is achieved, as shown by graph 20 in FIG. 1B. A line 25 can then be “best fit” to the phase angles, the slope of which representing the rate of change of phase over the range of frequencies. Based on the slope of line 25, a distance estimate can be predicted.

Unlike the RSSI method, the aforementioned approach using phase angles is generally less sensitive to changes in the physical environment, and thus more reliable in predicting distance in changing environments. While offering certain advantages, such an approach introduces disadvantages of its own when measuring tags attached to movable objects. More particularly, the approach would require several phase angle measurements in order to obtain a sufficient number of phase data points to provide an accurate approximation of the sawtooth wave function for a given tag to reader distance. Reading a tag once may take less than a second, but when multiple readings are required, such as 50 times corresponding to each of the different hop frequencies as with the case in FIG. 1A, it may take approximately 5 seconds to complete localization of the tag. In order to obtain accurate measurements, the tag would have to remain within the same location (or at least move within a tolerable movement range) over the sampling period. Otherwise, measurements can be rendered useless if the object moves significantly enough away from its original location. Thus, the phase angle method generally requires a time-consuming data gathering which can be inefficient when performing localization on moving tags.

Accordingly, there is a need for a distance estimation method that is fast, accurate, and environmentally robust.

### SUMMARY

Embodiments of the present disclosure provide methods and devices which accurately estimate distance to an RFID tag that overcome shortcomings experienced in existing localization techniques. According to an example embodiment, there is shown a method for determining a distance between a radio frequency identification (RFID) tag and a reader, including transmitting, by the reader, a plurality of interrogation signals to the RFID tag at a plurality of frequencies; receiving, by the reader, a plurality of response signals from the RFID tag in response to the plurality of interrogation signals; and determining a phase of each of the received plurality of response signals as well as a first distance estimate of the distance based on a signal strength measured from a first response signal of the plurality of response signals. Based upon the first distance estimate, the method alters one or more of the phases to achieve a linear phase trend of the phases, calculates a phase slope associated with the linear phase trend, and determines a second distance estimate of the distance based upon the phase slope.

In addition, the method may include determining a confidence interval about the first distance estimate, wherein each of the one or more of the phases is altered to approach a set of phase values defined by the confidence interval, and identifying an upper bound and a lower bound of the confidence interval, wherein each of the one or more of the phases is altered to a phase value defined by the upper and lower bounds of the confidence interval. The method may calculate a first phase slope and a second phase slope corresponding to the upper and lower bounds of the confidence interval, respectively, wherein each of the one or more of the phases is altered to approach a region of phase values bounded by the first and second phase slopes.

Another example embodiment may take the form of a device for determining a distance of a radio frequency identification (RFID) tag, including a reader configured to transmit a plurality of interrogation signals to the RFID tag at a plurality of frequencies, and receive therefrom a plurality of response signals in response to the plurality of interrogation signals; and a processor communicatively coupled to the reader. The processor may be operative to determine a phase of each of the received plurality of response signals, and a first distance estimate of the distance based on a signal strength measured from a first response signal of the plurality of response signals. Based on the determined phases and the first distance estimate, the processor may calculate a phase slope and determine a second distance estimate of the distance based upon the phase slope.

### BRIEF DESCRIPTION OF THE DRAWINGS

The above-mentioned and other features and advantages of the disclosed example embodiments, and the manner of attaining them, will become more apparent and will be better understood by reference to the following description of the disclosed example embodiments in conjunction with the accompanying drawings, wherein:

FIG. 1A illustrates plurality of phase angle measurements at different hop frequencies over a frequency range forming a generally sawtooth wave, according to a conventional phase measurement method;

FIG. 1B illustrates a transformed linear phase trend of the phase angles in FIG. 1B;

FIG. 2 illustrates an object detection system including an RFID tag detection device and a plurality of RFID tags, according to an example embodiment;

FIG. 3 illustrates communication between a radio device and an RFID tag;

FIG. 4 is a flowchart illustrating an example method of determining RFID tag distance, according to example embodiments of the present disclosure;

FIG. 5 illustrates a graph showing a relationship between RFID tag distance and RSSI according to an example embodiment;

FIG. 6 is an illustrative example of altering phase angles to predict a phase slope according to an example embodiment of the present disclosure;

FIG. 7 illustrates a linear phase pattern of the phase angles in FIG. 6 according to an example embodiment;

FIG. 8 is an illustrative example of altering phase angles to predict a phase slope according to another example embodiment of the present disclosure;

FIG. 9 is a flowchart illustrating an example method of determining RFID tag distance, according to another example embodiment of the present disclosure;

FIG. 10 is a graph illustrating an example relationship between distance and frequency location of sawtooth wave peaks;

FIG. 11 is a graph illustrating an example relationship between distance and phase period length;

FIG. 12 illustrates an example simplified sawtooth wave pattern formed using the graphs of FIGS. 10 and 11;

FIG. 13 is an illustrative example of altering phase angles to predict a phase slope according to another example embodiment of the present disclosure.

### DETAILED DESCRIPTION

It is to be understood that the present disclosure is not limited in its application to the details of construction and the arrangement of components set forth in the following description or illustrated in the drawings. The present disclosure is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted,” and variations thereof herein are used broadly and encompass direct and indirect connections, couplings, and mountings. In addition, the terms “connected” and “coupled” and variations thereof are not restricted to physical or mechanical connections or couplings.

Spatially relative terms such as “top”, “bottom”, “front”, “back” and “side”, and the like, are used for ease of description to explain the positioning of one element relative to a second element. Terms such as “first”, “second”, and the like, are used to describe various elements, regions, sections, etc. and are not intended to be limiting. Further, the terms “a” and “an” herein do not denote a limitation of quantity, but rather denote the presence of at least one of the referenced item.

Furthermore, and as described in subsequent paragraphs, the specific configurations illustrated in the drawings are intended to exemplify embodiments of the disclosure and that other alternative configurations are possible.

Reference will now be made in detail to the example embodiments, as illustrated in the accompanying drawings. Whenever possible, the same reference numerals will be used throughout the drawings to refer to the same or like parts.

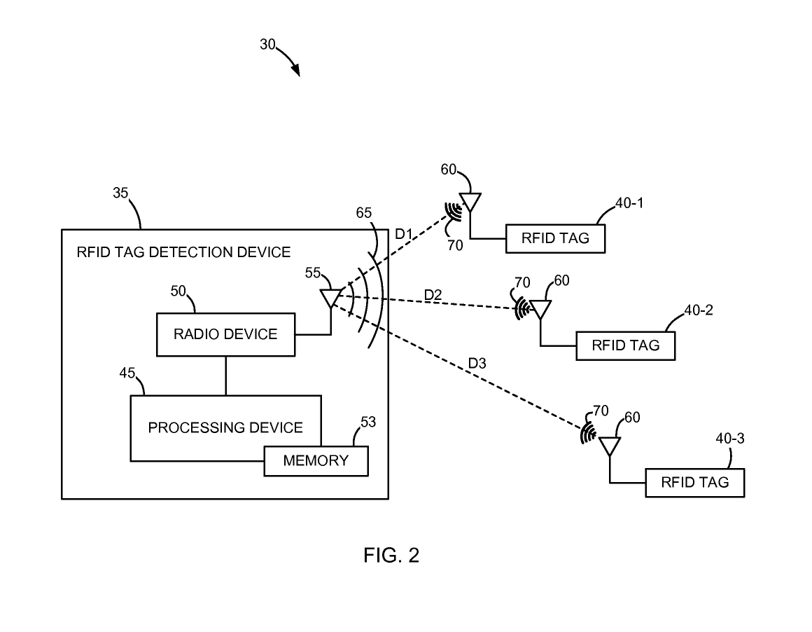

FIG. 2 shows an illustration of an object detection system 30 that may be used to provide localization services for identifying, determining, and tracking physical locations of different assets, equipment, devices, individuals, or other objects in a particular environment. As shown, object detection system 30 includes a radio frequency identification (RFID) tag detection device 35 and a plurality of RFID tags 40 that are attachable to objects of interest that need to be tracked.

RFID tag detection device 35 includes a processing device 45 and a radio device 50, such as a radio transceiver or transponder, communicatively coupled to processing device 45. Processing device 45 may include an associated memory 53 and may be a processor, microprocessor, controller and/or microcontroller formed as one or more Application Specific Integrated Circuits (ASICs). Memory 53 may be any memory device convenient for use with or capable of communicating with processing device 45. Processing device 45 may communicate with radio device 50 and serve to provide data to radio device 50 for transmission thereby, or to receive data therefrom for processing. In other alternative embodiments, RFID tag detection device 35 may be implemented in a variety of ways. For example, processing device 45 may be implemented as part of radio device 50 and may execute instructions maintained in memory 53 for performing operations or functions associated with radio device 50.

Radio device 50 may be derived from a wide variety of RFID readers capable of reading a number of passive, active, and/or semi-passive tags simultaneously within a read/interrogation range. Radio device 50 may include at least one antenna 55 and a circuit that is configurable to operate as a transmitter and a receiver. Radio device 50 generally uses antenna 55 to transmit radio frequency signals to the RFID tags 40 and receive response signals therefrom. Antenna 55 may be tuned to one or more frequencies at which radio device 50 interrogates and communicates with a particular RFID tag 40 within range. Antenna 55 may be implemented with one or more antennae. In one example, radio device 50 may have two or more antennae for localization.

Each RFID tag 40 may be a passive, active, or semi-passive tag, and may include a communications control unit (not shown) and an antenna 60. The communications control unit of each RFID tag 40 may decode and/or demodulate received information/interrogation signals from radio device 50, and encode, modulate, and transmit information/response signals to radio device 50 using antenna 60. Antenna 60 may be tuned to a frequency or frequencies at which radio device 50 communicates with RFID tag 40.

In operation, radio device 50 may broadcast a plurality of interrogation signals in the form of electromagnetic waves 65 to RFID tags 40 within interrogation range. In response, each RFID tag 40 within range may return a response signal in the form of electromagnetic waves 70 to radio device 50. Radio device 50 may use characteristics of received response signals to determine information associated with the responding RFID tag 40. For example, radio device 50 may identify a responding RFID tag and determine a distance Dₙ thereof based on response signals received therefrom.

In an example embodiment, RFID tag detection device 35 may be configured for and/or capable of measuring RSSI of a response signal received from a responding RFID tag 40, and calculating a distance estimate of the RFID tag 40 based on the measured RSSI. As conventionally known, a response signal transmitted by an RFID tag loses power as it travels through air due to reflection, refraction, absorption, and other environmental factors. Thus, as the distance between an RFID tag and radio device 50 increases, signal strength of response signals received by radio device 50 generally decreases. For example, in FIG. 2, three RFID tags 40-1, 40-2, and 40-3 are illustrated with RFID tag 40-1 being relatively closest to radio device 50 at a distance D1 and then increasing in distance with RFID tags 40-2 and 40-3 at distances D2 and D3, respectively. Accordingly, response signals transmitted by RFID tag 40-1 may be stronger in signal strength as received by radio device 50 compared to signal strengths of response signals received from RFID tags 40-2 and 40-3. Radio device 50 can receive a response signal from an RFID tag 40 using antenna 55 and decode the received response signal to identify the RFID tag 40. Additionally, the amplitude of the received response signal may be examined to obtain a measure of RSSI associated with the received response signal. The measured RSSI may then be used to calculate a distance estimate of the RFID tag 40.

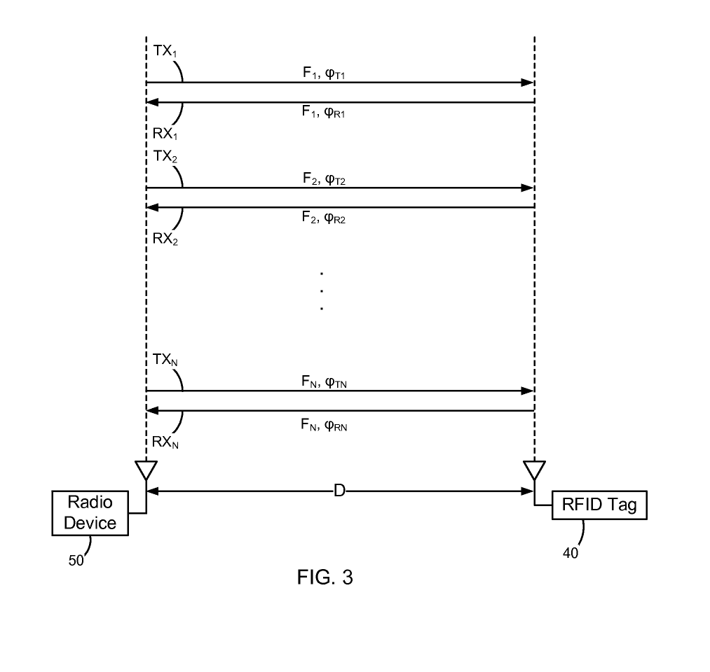

In another example embodiment, RFID tag detection device 35 may be configured for and/or capable of measuring phase associated with response signals received from RFID tags 40. With reference to FIG. 3, an example communication between radio device 50 and RFID tag 40 is illustrated. Radio device 50 may transmit a plurality of signals TX₁, TX₂, . . . , TX_{N} at different frequencies F₁, F₂, . . . F_{N}, respectively, to interrogate RFID tag 40, and receive therefrom corresponding response signals RX₁, RX₂, . . . , RX_{N} for each transmitted signal TX₁, TX₂, . . . , TX_{N} at corresponding frequencies F₁, F₂, . . . , F_{N}. In this example, transmitted signals TX₁, TX₂, . . . , TX_{N} may be transmitted by radio device 50 with initial phases φ_{T1}, φ_{T2}, . . . , φ_{TN}, respectively. Upon arriving at radio device 50, response signals RX₁, RX₂, . . . , RX_{N} may have respective phases φ_{R1}, φ_{R2}, . . . φ_{RN} that differ from the initial phases φ_{T1}, φ_{T2}, . . . , φ_{TN} of corresponding interrogation signals TX₁, TX₂, . . . , TX_{N}. Phases φ_{R1}, φ_{R2}, . . . , φ_{RN} of the received response signals RXₙ generally varies with each frequency Fₙ, and this variation in phase with respect to the change in frequency is proportional to the reader to tag distance. Accordingly, RFID tag detection device 35 may utilize the changes in phase to calculate an estimate of the distance D between radio device 50 and RFID tag 40, as will be explained in detail below. Signal phase may be determined using any of a variety of techniques known in the art.

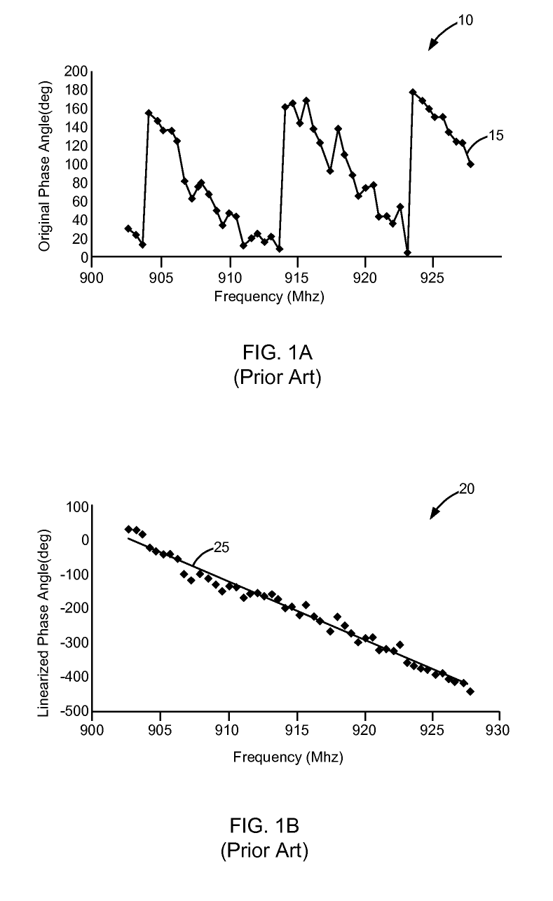

In accordance with example embodiments of the present disclosure, object detection system 30 may perform distance measurements on a given RFID tag 40 of interest using techniques that utilize both RSSI and phase of response signals received from the RFID tag of interest. Generally, a distance measurement may be performed on the RFID tag 40 of interest using RSSI, and phase measurements of response signals at different frequencies may be obtained for the same RFID tag 40. The phase measurements may then be altered based on the distance measurement ascertained by the RSSI method to determine an estimate of a phase slope corresponding to the distance of the RFID tag 40 from the radio device 50. Thereafter, a final distance estimate of the RFID tag 40 may be determined based on the estimated phase slope. In this way, RSSI method may be used to inform how the phase slope corresponding to the RFID tag distance may be approximated, and thus may compensate for the requirement of having relatively large numbers of phase measurements at the hop frequencies to obtain a phase slope as previously described with respect to FIG. 1B. At least two phase measurements at selected frequencies may be needed to provide localization, as will be explained in greater detail below. Thus, techniques provided herein may permit a reduction in the number of required phase measurements such that the amount of time needed for accurate RFID tag localization using phase angle method may be reduced.

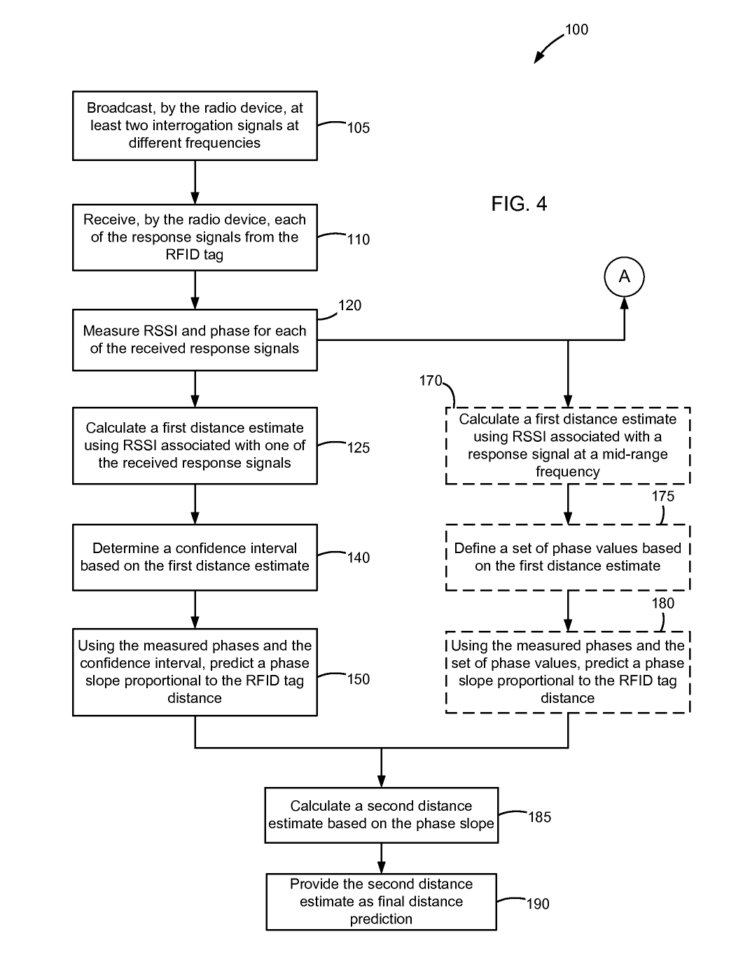

Referring now to FIG. 4, a flowchart of an example method 100 of determining distance of an RFID tag using both RSSI method and phase method is illustrated, according to one example embodiment of the present disclosure.

At block 105, radio device 50 may broadcast at least two interrogation signals TX at different frequencies to interrogate RFID tag 40 within interrogation range. A carrier frequency at which a signal is transmitted can be any available or permitted frequency in the radio frequency spectrum. For example, carrier frequencies may be selected from an available set of frequencies in a frequency hopping system in a particular geographic location. In an example embodiment, selected carrier frequencies may be spaced apart by known or predetermined frequency intervals. In another example embodiment, frequency selection may be random. In still another example embodiment, selected frequencies may be substantially distributed over the available range of frequencies. As will be appreciated, any suitable carrier frequencies may be selected.

In response to each of the at least two interrogation signals TX, RFID tag 40 may respond by returning response signals RX at each corresponding frequency. Radio device 50 may receive each of the response signals RX at block 110, and measure both RSSI and phase of each received response signal RX at block 120.

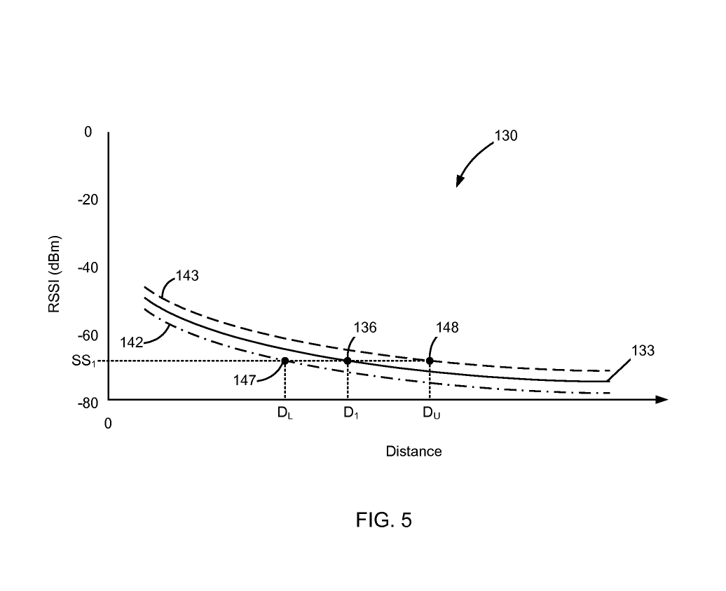

At block 125, a first estimate of the distance between RFID tag 40 and radio device 50 may be determined using measured RSSI associated with one of the received response signals. In an example embodiment, the first distance estimate may be determined based on an empirically determined relationship between RSSI and reader-to-tag distance. For example, in FIG. 5, a graph 130 having a curve 133 that represents a relationship between RSSI and distance is illustrated. For a given RSSI value, a corresponding distance may be determined using curve 133. As an example, an RSSI value SS₁ measured from one received signal at a particular frequency corresponds to a point 136 on curve 133 and has a corresponding distance D₁ which may constitute the first distance estimate. It will be appreciated that graph 130 is presented for purposes of illustration and, thus, should not be considered limiting. In other alternative embodiments, other techniques for determining distance estimates based on RSSI measurements may be used.

At block 140, a confidence interval for the distance between RFID tag 40 and radio device 50 may be determined based on the first distance estimate D₁, and/or based on the measured RSSI used to determine the first distance estimate D₁. Generally, the confidence interval may define a distance range about the first distance estimate D₁ that provides relatively high-probability estimates of the actual RFID tag distance. The confidence level of the confidence interval may be set to any desired value, and in one example may be set to about 95%. Confidence bounds define the width of the confidence interval, and define lower and upper values of distances about the first distance estimate D₁. As an example, FIG. 5 further depicts example confidence bounds 142 and 143 for curve 133. Corresponding to the measured RSSI value SS₁ are two points 147 and 148 along lower bound 142 and upper bound 143, respectively. Accordingly, a lower confidence limit for the distance may be D_{L} corresponding to point 147 along lower bound 142, and an upper confidence limit may be D_{U} corresponding to point 148 along curve 143. It is understood that the above example is only for purposes of illustration. It is contemplated that confidence bounds and/or limits may be determined using various other techniques.

At block 150, the measured phase angles of the received response signals determined at block 120 and the confidence interval determined at block 140, may be used to predict a phase slope (which corresponds to change in phase angle with respect to change in frequency as previously described with respect to phase angle method) that is proportional to the RFID tag distance. In an example embodiment, relationship between distance and phase slope may be expressed by the following Equation 1:

$$d = - \frac{c}{4 π} \frac{\partial ϕ}{\partial f} + β \qquad Eq . ( 1 )$$

where d is the distance between RFID tag and radio device, c is the speed of light,

$$\frac{\partial ϕ}{\partial f}$$

is the phase slope, and β is an empirically determined distance value used to correct distance offset from the actual RFID tag distance caused in part by system or environmental constraints. In one example, β may be between about −5 meters and about −2 meters, such as about −4 meters. As will be appreciated, however, the value of β can vary depending on the particular setup, such as based upon the coupling and length of the cable between radio device 50 and antenna 55. Using Eq. (1), phase slope can be calculated given a particular distance, and conversely, distance can be calculated given a particular phase slope. Thus, given the phase slope that is proportional to the RFID tag distance, the second distance estimate can be calculated using Eq. (1) at block 185.

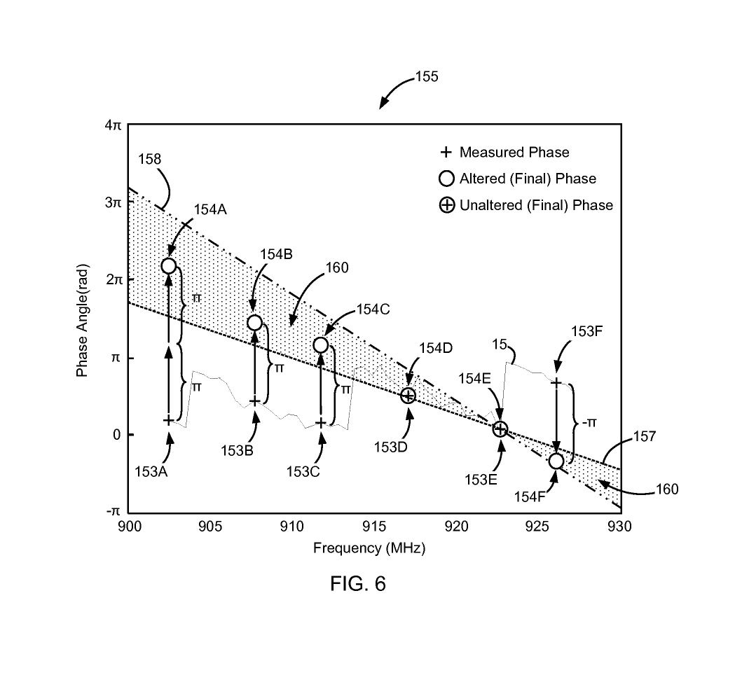

With reference to FIG. 6, an illustrative example is depicted for determining the phase slope (block 150) for use in calculating the second distance estimate (block 185). Various phase data points 153A-153F corresponding to measured phase angles associated with the received response signals RX at different frequencies are plotted against a graph 155 of phase angle versus frequency. In the example shown, the example phase data points 153 correspond to selected phase angles shown in FIG. 1A at different frequency locations. To more clearly illustrate this, the sawtooth wave 15 in FIG. 1A is superimposed on graph 155 such that the example phase data points 153 are shown as points on the sawtooth wave 15 at different frequencies thereof. As will become more apparent hereinafter, the example phase data points 153 are selected to show that only a few, and not necessarily all, of the phase angles across the frequency range can be used to approximate a phase slope and consequently to predict RFID tag distance, in contrast to the method described with respect to FIG. 1A.

In order to approximate the phase slope corresponding to the RFID tag distance, a set or region of phase values that would most likely contain phase angles of the phase slope may be defined. In this example, boundaries for the region may be determined based on the previously determined confidence interval. In particular, phase slopes corresponding to each of the lower confidence limit D_{L} and the upper confidence limit D_{U} may be calculated using Eq. (1), and used as boundary lines to define the region of phase values. In FIG. 6, a first phase slope 157 and a second phase slope 158 corresponding to the lower and upper confidence limits D_{L} and D_{U}, respectively, are shown to intersect at phase data point 153E. In an example embodiment, phase data point 153E may correspond to the phase angle associated with the response signal from which the first distance estimate D₁ was measured. A region 160 of potential phase values is thereby defined between first and second phase slopes 157 and 158.

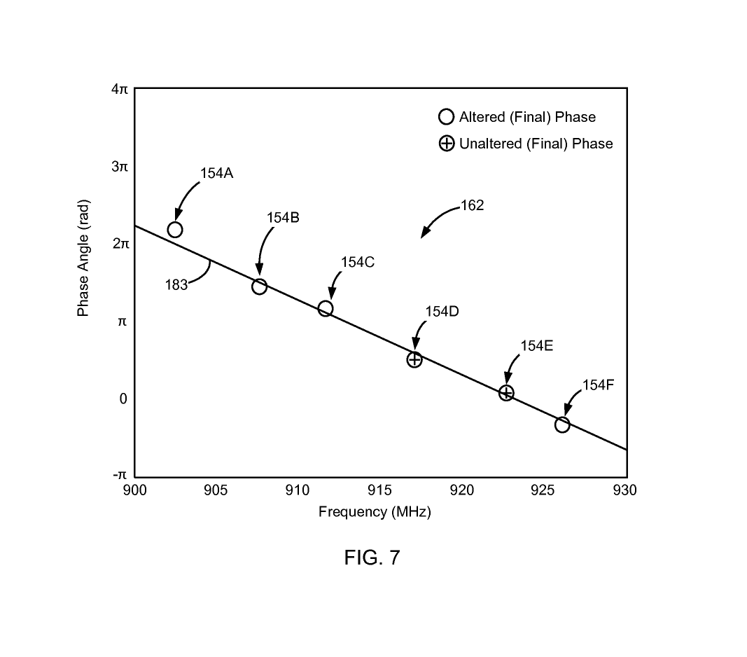

Thereafter, at least one of the phase data points 153 other than phase data point 153E may be altered to approach towards the region 160 bounded by first and second phase slopes 157 and 158. More particularly, phase data points that do not lie within the region 160 may either be incremented or decremented by a predetermined angular value (or a multiple thereof) until all phase data points 153 lie within or are relatively close to the region 160. In an example embodiment, the predetermined angular value may be π (pi) radians or, alternatively, 180° if phase measurements are in degrees. The amount of increments or decrements may depend upon the frequency location of a phase data point 153, and/or its relative location on the sawtooth wave 15. In the example shown, phase data point 153A is incremented by 2π, each of phase data points 153B and 153C are incremented by π, phase data point 153D remains unaltered, and phase data point 153F is decremented by π. Accordingly, after the alterations at appropriate locations, final phase data points 154 lie within or relatively close to the region 160. In FIG. 7, the final phase data points 154 (both altered and unaltered) that lie within or relatively close to the region 160 are shown on a separate graph 162 exhibiting a substantially linear phase trend or pattern.

Altering of the phase data points to produce the substantially linear phase pattern in FIG. 7 may alternatively be conducted differently from using a region defined by a confidence interval as previously described with respect to FIG. 6. In an alternative example embodiment, a response signal at a frequency in the middle of the frequency range may be used to define a function that provides a set of phase values towards which phase data points may be altered to approach.

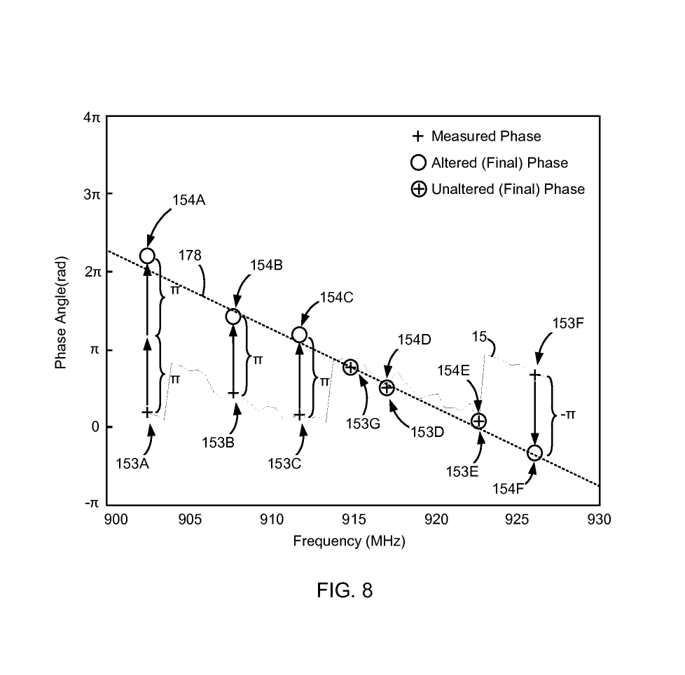

More particularly, and referring again to FIG. 4, after measuring RSSI and phase for each received response signal at block 120, a first distance estimate may alternatively be determined using measured RSSI of a mid-range frequency response signal at block 170. At block 175, the first distance estimate may be used to calculate an initial phase slope using Eq. (1), and the calculated initial phase slope may be used to define the set of phase values. For example, with reference to FIG. 8, a phase data point 153G associated with a mid-range frequency response signal is shown at the middle of the frequency range at about 915 MHz. Measured RSSI of the mid-range frequency response signal may be used to calculate the initial phase slope 178, and the initial phase slope 178 may be drawn to intersect phase data point 153G. A set of phase values is thereby defined by the line of initial phase slope 178.

At block 180 (FIG. 4), a new phase slope to be used for calculating the second distance estimate may be predicted using the measured phases determined at block 120 and the set of phase values defined at block 175. In an example embodiment, at least one phase data point may be taken at each side of phase data point 153G, such as at relatively low (e.g., at 903 MHz) and high (e.g., at 927 MHz) frequencies of the frequency range. In the example shown in FIG. 8, various phase data points 153A-153F are illustrated corresponding to the same example phase data points used in FIG. 6, and which are shown as points on sawtooth wave 15. In order to approximate the new phase slope, at least one of the phase data points 153A-153F may be altered to approach towards the line of phase slope 178. One or more of phase data points 153A-153F may be incremented or decremented by a predetermined angular value, such as pi radians, until all phase data points lie relatively close to phase slope 178. In the example shown, phase data point 153A is incremented by 2π, each of phase data points 153B and 153C is incremented by π, phase data points 153D and 153E remain unaltered, and phase data point 153F is decremented by π. Accordingly, after the alterations at appropriate locations, a difference between final phase data points 154 and a corresponding phase point on phase slope 178 at each distinct frequency location is substantially minimized As can be observed, the phase pattern formed by the final phase data points 154 (both altered and unaltered) that lie relatively close to phase slope 178 in this example embodiment closely follows or is relatively the same as that shown in FIG. 7.

Once the phase data points are altered to form the substantially linear phase pattern (using either of the methods utilizing confidence interval or initial phase slope estimate), a best-fit linear function of the phase pattern may be generated. For example, linear regression techniques may be used to determine a best-fit line 183 for the final phase data points as shown in FIG. 7. A value for the slope of best-fit line 183 may then be determined. The slope of line 183 may represent the phase slope corresponding to the RFID tag distance, and thus may be used in Eq. (1) to calculate the second distance estimate at block 185. The second distance estimate may be provided as a final distance prediction at block 190.

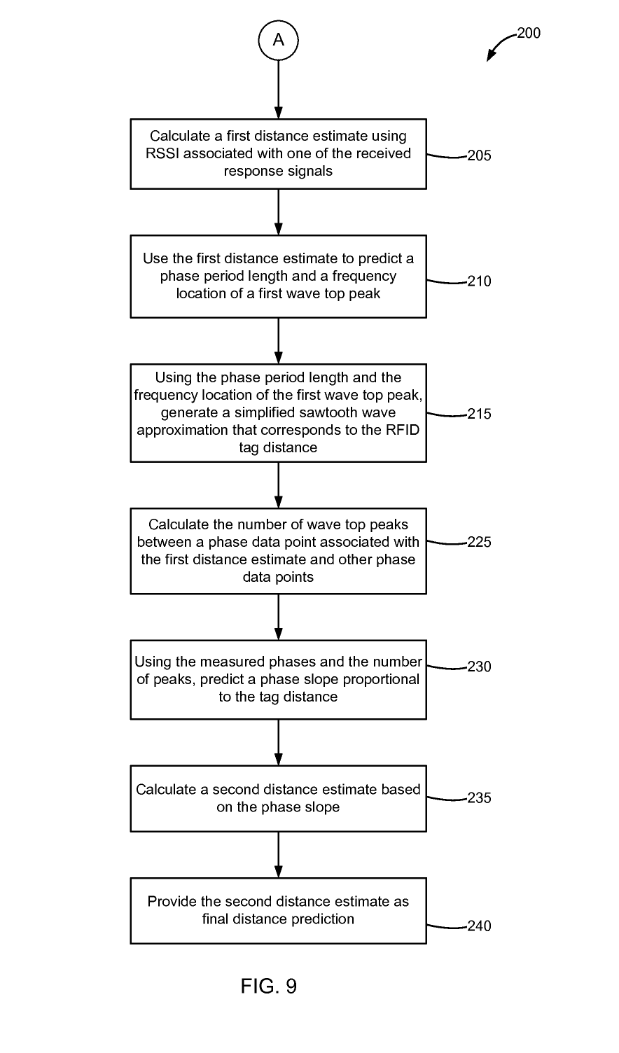

Referring now to FIG. 9, a flowchart of another example method 200 of determining distance of an RFID tag using both RSSI method and phase method is illustrated, according to another example embodiment of the present disclosure. Generally, example method 200 utilizes a simplified sawtooth pattern which approximates a sawtooth wave and corresponds to the relationship between frequency, phase and the RFID tag distance, in order to form a linear phase pattern from which a phase slope may be determined. With varying RFID tag distances, characteristics of the simplified sawtooth pattern may vary. In this example embodiment, characteristics of the simplified sawtooth pattern for a given RFID tag distance is determined based on a distance estimate thereof calculated using RSSI, and phase data points are altered based on their relative locations on the simplified sawtooth pattern.

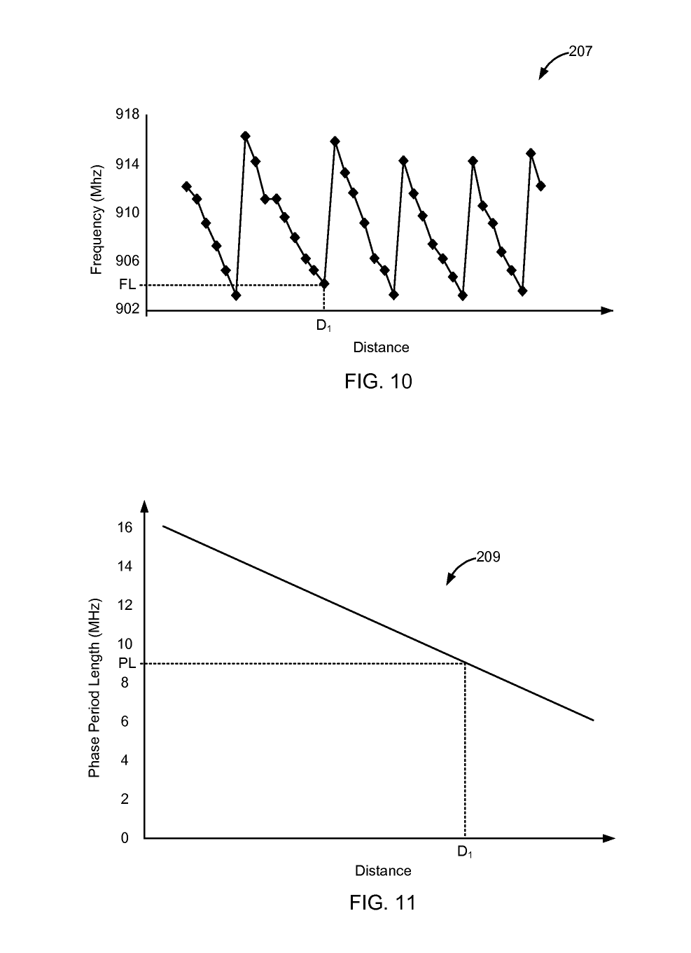

RSSI and phase associated with at least two response signals may be determined by initially following the steps associated with blocks 105 to 120 of method 100 in FIG. 4. At block 205, a first distance estimate using RSSI of one of the at least two response signals may be calculated. After determining the first distance estimate, the first distance estimate may be used to predict a frequency location at which a first wave top peak of the simplified sawtooth pattern occurs, and a phase period length thereof, at block 210. In an example embodiment, the frequency location of the first wave top peak and phase period length may be determined using empirically derived data. For example, FIG. 10 illustrates a graph 207 showing the relationship between RFID tag distance and frequency location (in MHz) of first-occurring wave top peaks. Meanwhile, FIG. 11 illustrates a graph 209 showing a relationship between RFID tag distance and phase period length (in MHz). Thus, for a given distance value, a corresponding first wave top peak frequency location may be determined using graph 207, and a corresponding phase period length may be determined using graph 209. In the example shown in FIG. 10, first distance estimate D₁ corresponds to having a first wave top peak occurring at a frequency location FL (at about 904 MHz). In FIG. 11, first distance estimate D₁ corresponds to having a phase period length PL (about 9 MHz).

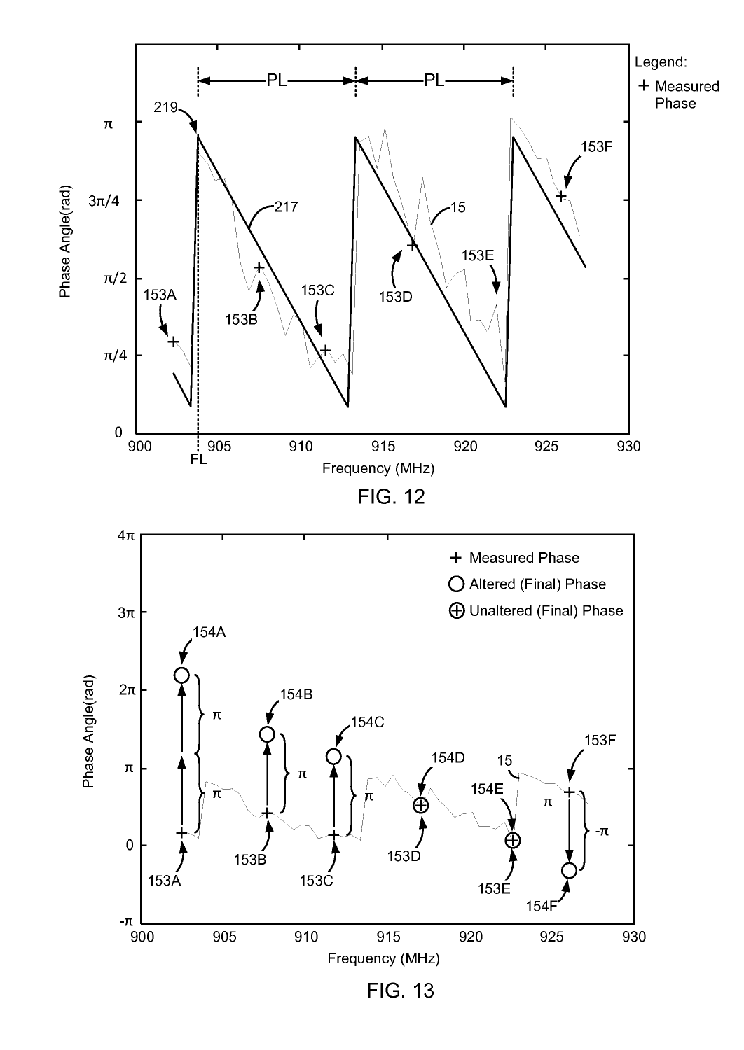

Using the first wave top peak frequency location FL and the phase period length PL, a sawtooth wave approximation corresponding to the RFID tag distance may be generated at block 215. As an illustrative example, a simplified sawtooth wave pattern 217 is shown in FIG. 12 having its first top peak 219 occurring at frequency FL, and having a phase period length PL over the frequency range. Further illustrated are various example phase data points 153A-153F which correspond to the same example phase data points used in FIGS. 6 and 8, and which are shown as points on sawtooth wave 15.

At block 225, the number of top peaks between a reference phase data point and the remaining phase data points may be calculated. In an example embodiment, the reference phase data point may be associated with the response signal from which the first distance estimate D₁ is determined. For example, taking phase data point 153D as the reference phase data point, the number of top peaks occurring between phase data point 153D and each of phase data points 153A, 153B, 153C, 153E, and 153F are 2, 1, 1, 0, and 1, respectively.

At block 230, a phase slope proportional to the tag distance may be predicted using the phase angles of the phase data points 153 and the corresponding number of top peaks between phase data points. In an example embodiment, in order to predict the phase slope, one or more of the phase data points 153 other than reference phase data point 153D may be altered based on the corresponding number of top peaks. The number of top peaks may determine the number of increments or decrements of a predetermined angular value, such as pi radians, that are added to or subtracted from a particular phase data point 153. For example, phase data points 153A, 153B, and 153C at the lower frequency side of phase data point 153D are incremented by 2π, π, and π, respectively, due to 2, 1, and 1 top peak(s), respectively, occurring between each of phase data points 153A, 153B, 153C and reference phase data point 153D. On the other hand, phase data point 153F at the higher frequency side of phase data point 153D is decremented by π because of 1 occurring top peak between phase data points 153D and 153F. Phase data point 153E remains unaltered due to an absence of a top peak occurring between phase data points 153D and 153E. Accordingly, after the alterations of phase data points at appropriate locations, final phase data points 154 (both altered and unaltered) may form a substantially linearized phase pattern. As can be observed, the phase pattern formed by the final phase data points 154 in this example embodiment closely follows or is relatively the same as that shown in FIG. 7. Once the phase data points are altered to form the substantially linearized phase pattern, a best-fit linear function of the phase pattern may be generated using different techniques, as described above with respect to FIG. 7. A value for the slope of the best-fit line may then be determined as the phase slope.

At block 235 (FIG. 9), the phase slope may be used in Eq. (1) to calculate the second distance estimate. The second distance estimate may then be provided as a final distance prediction at block 240.

In the aforementioned illustrative examples, six or seven phase data points have been used to predict the phase slopes, and consequently to determine second distance estimates. However, it will be understood that utilizing less than six phase data points, such as two phase data points, or more than six or seven phase data points, may be implemented. Additional phase data points, though, may provide the opportunity to make more accurate approximations or predictions of the phase slope.

With the above example embodiments, the distance between an RFID tag and a reader may be predicted by using phase measurements at different frequencies, and altering the phase measurements based on information ascertained by RSSI measurement to appropriately substantially align the phase measurements and obtain a phase slope corresponding to the distance. At least two phase measurements may be needed such that the example embodiments may take only a fraction of the amount of time required for the example phase method associated with FIGS. 1A and 1B. Accordingly, the above example embodiments may allow distance estimations with the accuracy and environmental robustness of phase method, and with significantly increased speed by using RSSI.

The foregoing description of several example embodiments of the invention has been presented for purposes of illustration. It is not intended to be exhaustive or to limit the invention to the precise steps and/or forms disclosed, and obviously many modifications and variations are possible in light of the above teaching. It is intended that the scope of the invention be defined by the claims appended hereto.

What is claimed is:

1. A method for determining a distance between a radio frequency identification (RFID) tag and a reader, comprising:
transmitting, by the reader, a plurality of interrogation signals to the RFID tag at a plurality of frequencies;
receiving, by the reader, a plurality of response signals from the RFID tag in response to the plurality of interrogation signals;
determining a phase of each of the received plurality of response signals, and a first distance estimate of the distance based on a signal strength measured from a first response signal of the plurality of response signals;
based upon the first distance estimate, altering one or more of the phases to achieve a phase trend of the phases;
calculating a phase slope associated with the phase trend; and
determining a second distance estimate of the distance based upon the phase slope.

2. The method of claim 1, further comprising determining a confidence interval about the first distance estimate, wherein each of the one or more of the phases is altered to approach a set of phase values defined by the confidence interval.

3. The method of claim 2, further comprising identifying an upper bound and a lower bound of the confidence interval, wherein each of the one or more of the phases is altered to a phase value defined by the upper and lower bounds of the confidence interval.

4. The method of claim 3, further comprising calculating a first phase slope and a second phase slope corresponding to the upper and lower bounds of the confidence interval, respectively, wherein each of the one or more of the phases is altered to approach a region of phase values bounded by the first and second phase slopes.

5. The method of claim 4, wherein the first and second phase slopes intersect at a phase point associated with the first response signal.

6. The method of claim 1, further comprising defining, using the first distance estimate, a function that provides a set of phase values, wherein each of the one or more of the phases is altered to approach a phase value of the set of phase values.

7. The method of claim 6, wherein the function corresponds to a phase slope estimate that is proportional to the first distance estimate.

8. The method of claim 1, wherein the calculating the phase slope includes generating a best-fit linear function of the phase trend and determining a slope thereof, the slope corresponding to the phase slope.

9. The method of claim 1, wherein the phase trend comprises a substantially linear phase trend and the altering includes adding or subtracting an angular value to or from each one or more of the phases such that the phases achieve the substantially linear phase trend.

10. The method of claim 8, wherein the angular value is 180° or pi radians, or an integer multiple thereof.

11. A device for determining a distance of a radio frequency identification (RFID) tag, comprising:
a reader configured to transmit a plurality of interrogation signals to the RFID tag at a plurality of frequencies, and receive therefrom a plurality of response signals in response to the plurality of interrogation signals; and
a processor communicatively coupled to the reader and operative to:
determine a phase of each of the received plurality of response signals, and a first distance estimate of the distance based on a signal strength measured from a first response signal of the plurality of response signals;
based on the determined phases and the first distance estimate, calculate a phase slope; and
determine a second distance estimate of the distance based upon the phase slope.

12. The device of claim 11, wherein the processor predicts the phase slope by altering one or more of the phases to approach a set of phase values defined in part by the first distance estimate.

13. The device of claim 12, wherein the processor is further operative to determine a confidence interval relative to the first distance estimate, the set of phase values being defined by the confidence interval.

14. The device of claim 12, wherein the processor is further operative to define a function corresponding to a phase slope estimate that is proportional to the first distance estimate, the function defining the set of phase values.

15. The device of claim 12, wherein the altering includes adding or subtracting an angular value to or from each of the one or more of the phases such that the phases achieve a substantially linearized phase pattern.

16. A non-transitory computer readable storage medium having stored thereon instructions that when executed by a machine result in the following operations:
determining phases of a plurality of response signals at a plurality of frequencies received from a radio frequency identification (RFID) tag in response to interrogation signals by a reader at the plurality of frequencies;
calculating a first distance estimate of a distance between the RFID tag and the reader based on a signal strength measured from a first response signal of the plurality of response signals;
based on the phases and the first distance estimate, calculating a phase slope; and
determining a second distance estimate of the distance based upon the phase slope.

17. The computer readable storage medium of claim 16, wherein the predicting the phase slope includes altering one or more of the phases to achieve a substantially linear phase trend thereof and determining a slope associated with the linear phase trend, the slope corresponding to the phase slope.

18. The computer readable storage medium of claim 17, wherein the altering includes altering the one or more of the phases to approach a set of phase values defined in part by the first distance estimate.

19. The computer readable storage medium of claim 18, wherein the set of phase values is defined by a confidence interval relative to the first distance estimate.

20. The computer readable storage medium of claim 18, wherein the set of phase values is defined by a function corresponding to a phase slope estimate that is proportional to the first distance estimate.
